(19) United States
(12) Patent Application Publication
(10) Pub. No.: US 2012/0312776 A1
(43) Pub. Date: Dec. 13, 2012

(54) METHOD FOR MAKING TOUCH PANEL

(75) Inventors: JIA-SHYONG CHENG, Tu-Cheng (TW); PO-SHAN HUANG, Tu-Cheng (TW); PO-SHENG SHIH, Tu-Cheng (TW); CHUN-YI HU, Tu-Cheng (TW); CHIH-HAN CHAO, Tu-Cheng (TW); JEAH-SHENG WU, Tu-Cheng (TW)

(73) Assignee: SHIH HUA TECHNOLOGY LTD., Miaoli (TW)

(21) Appl. No.: 13/339,664

(22) Filed: Dec. 29, 2011

(30) Foreign Application Priority Data
Jun. 9, 2011 (TW) 100120155

(51) Int. Cl. H05K 3/06; H05K 3/08; B32B 38/10; B82Y 30/00

(52) U.S. Cl. 216/20; 156/247; 977/932

(57) ABSTRACT

A method for making a plurality of touch panels one time which includes the following steps. A substrate is provided. The substrate has a surface defining a plurality of target areas with each including a touch-view area and a trace area. An adhesive layer is formed on the surface of the substrate. The adhesive layer on the trace areas is solidified. A carbon nanotube layer is formed on the adhesive layer. The adhesive layer on the touch-view area is solidified. The carbon nanotube layer on the trace areas is removed to obtain a plurality of transparent conductive layers spaced from each other. An electrode and a conductive trace are formed on each target area. A plurality of touch panels is obtained by cutting the substrate.

### CROSS-REFERENCE TO RELATED APPLICATIONS

This application claims all benefits accruing under 35 U.S.C. §119 from Taiwan Patent Application No. 100120155, filed on Jun. 9, 2011, in the Taiwan Intellectual Property Office, the contents of which are hereby incorporated by reference. This application is related to applications entitled, “TOUCH PANEL”, filed ______ (Atty. Docket No. US39777); and “METHOD FOR MAKING TOUCH PANEL”, filed ______ (Atty. Docket No. US39779); and “METHOD FOR MAKING TOUCH PANEL”, filed ______ (Atty. Docket No. US39781); and “TOUCH PANEL AND METHOD FOR MAKING THE SAME”, filed ______ (Atty. Docket No. US39782); and “METHOD FOR MAKING TOUCH PANEL”, filed ______ (Atty. Docket No. US39784); and “METHOD FOR MAKING TOUCH PANEL”, filed ______ (Atty. Docket No. US39785); and “PATTERNED CONDUCTIVE ELEMENT”, filed ______ (Atty. Docket No. US39786); and “METHOD FOR MAKING PATTERNED CONDUCTIVE ELEMENT”, filed ______ (Atty. Docket No. US39787); and “METHOD FOR MAKING PATTERNED CONDUCTIVE ELEMENT”, filed ______ (Atty. Docket No. US39790); and “TOUCH PANEL”, filed ______ (Atty. Docket No. US39792); and “TOUCH PANEL”, filed ______ (Atty. Docket No. US39793).

### BACKGROUND

1. Technical Field

The present disclosure relates to methods for making touch panel, particularly, to a method for making a carbon nanotube based touch panel.

2. Description of Related Art

In recent years, various electronic apparatuses such as mobile phones, car navigation systems have advanced toward high performance and diversification. There is continuous growth in the number of electronic apparatuses equipped with optically transparent touch panels in front of their display devices such as liquid crystal panels. A user of such electronic apparatus operates it by pressing a touch panel with a finger or a stylus while visually observing the display device through the touch panel. Thus a demand exists for such touch panels which superior in visibility and reliable in operation. Due to a higher accuracy and a low-cost of the production, the resistance-type or capacitance-type touch panels have been widely used.

A conventional resistance-type or capacitance-type touch panel includes a conductive indium tin oxide (ITO) layer as an optically transparent conductive layer. However, the ITO layer is generally formed by means of ion-beam sputtering which requires an expensive vacuum device. Furthermore, the ITO layer needs to be etched by laser beam to form pattern. Thus, the method for making touch panel is relatively complicated and high cost.

What is needed, therefore, is to provide a method for making a touch panel which can overcome the short come described above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a flowchart of one embodiment of a method for making a touch panel.

FIG. 2 is a schematic, top view of one embodiment of step (S10) of FIG. 1.

FIG. 3 is a schematic, top view of one embodiment of step (S20) of FIG. 1.

FIG. 4 is a schematic, top view of one embodiment of step (S30) of FIG. 1.

FIG. 5 is a schematic, top view of one embodiment of step (S40) of FIG. 1.

FIG. 6 is a schematic, top view of one embodiment of step (S60) of FIG. 1.

FIG. 7 is a schematic, top view of one embodiment of step (S70) of FIG. 1.

FIG. 8 is a Scanning Electron Microscope (SEM) image of a carbon nanotube film.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

References will now be made to the drawings to describe, in detail, various embodiments of the present methods for making the touch panels. The methods can be used to make a single-point resistance-type touch panel or a multi-point resistance-type touch panel, a single-point capacitance-type touch panel or a multi-point capacitance-type touch panel.

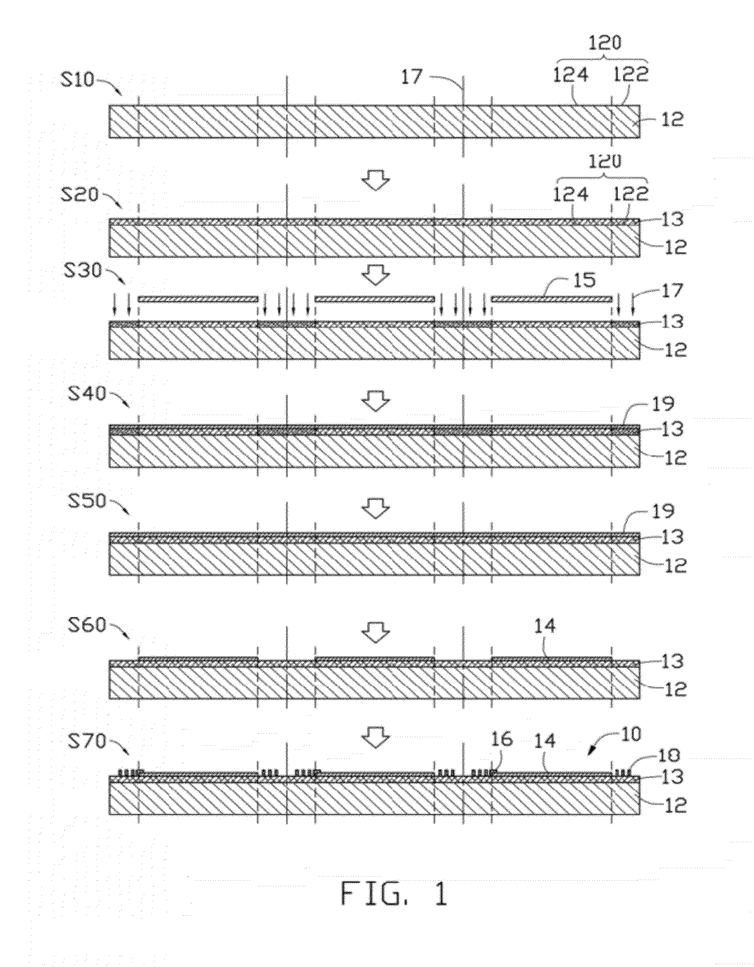

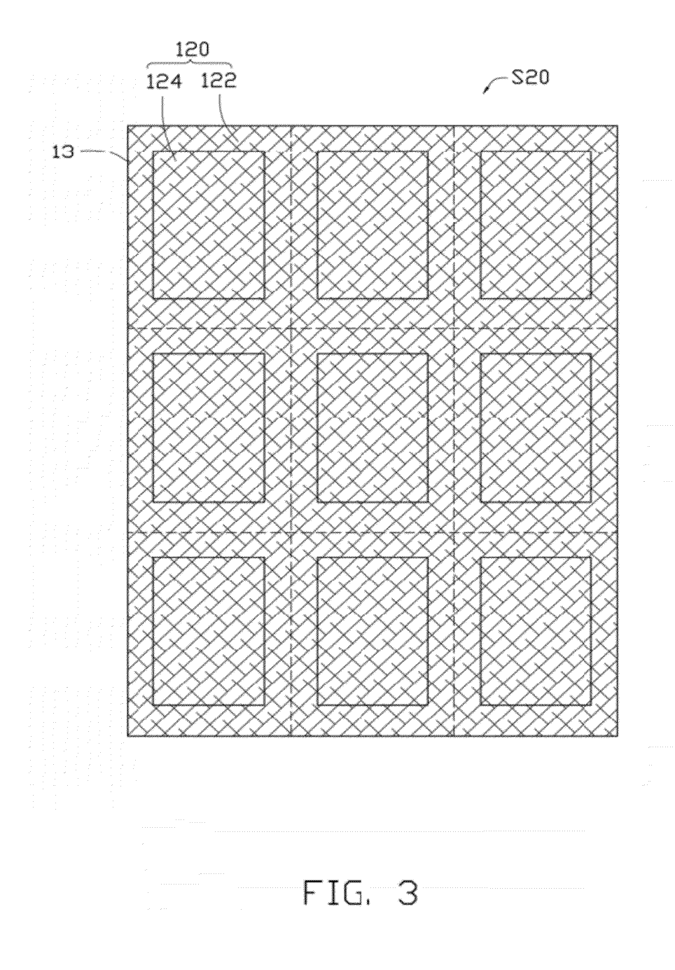

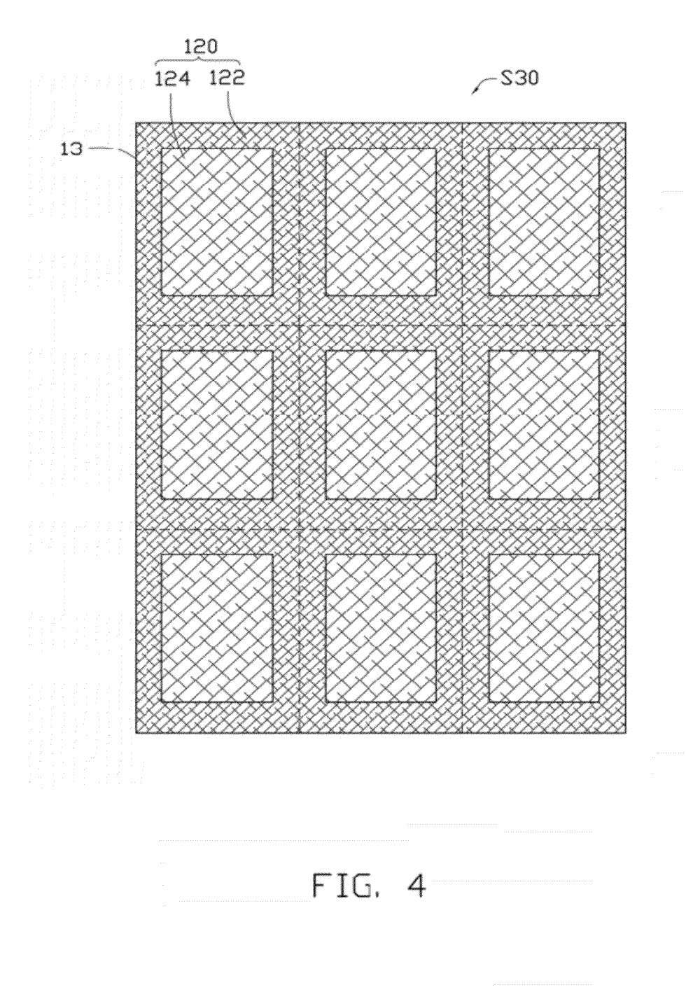

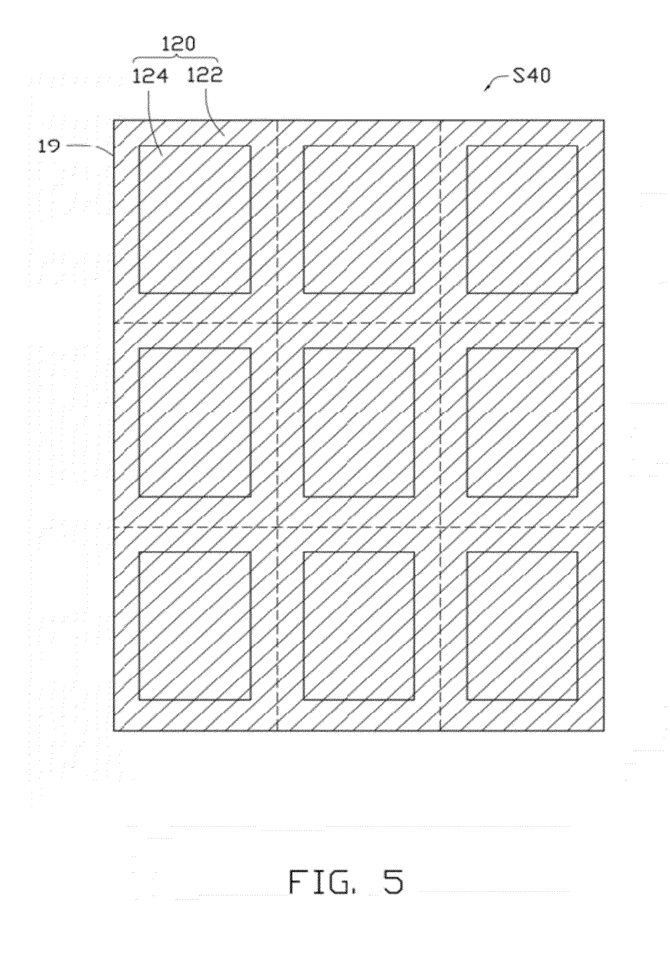

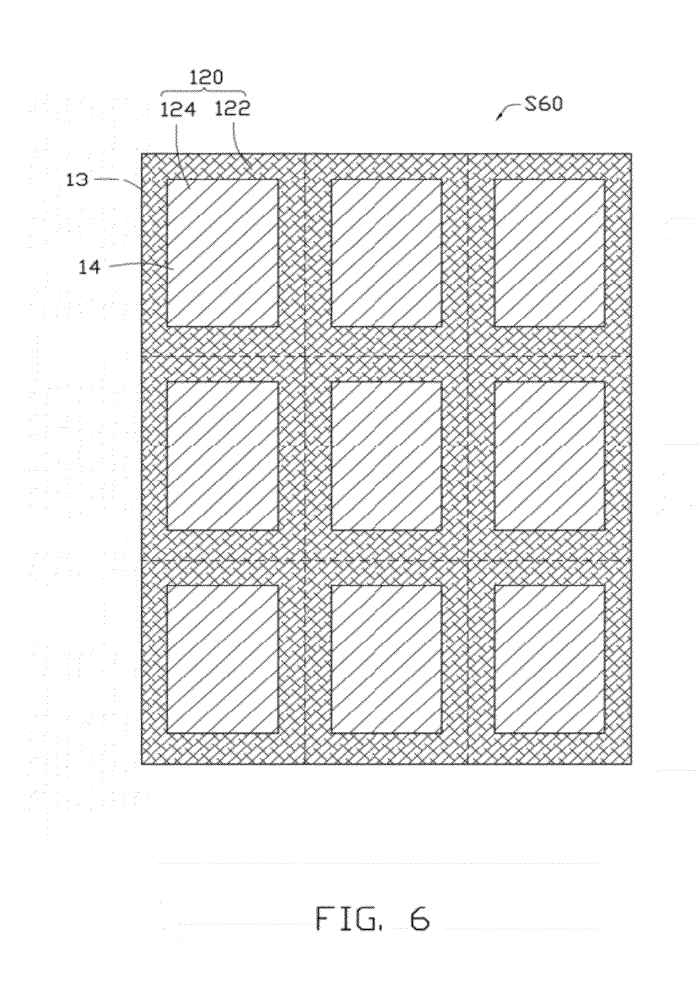

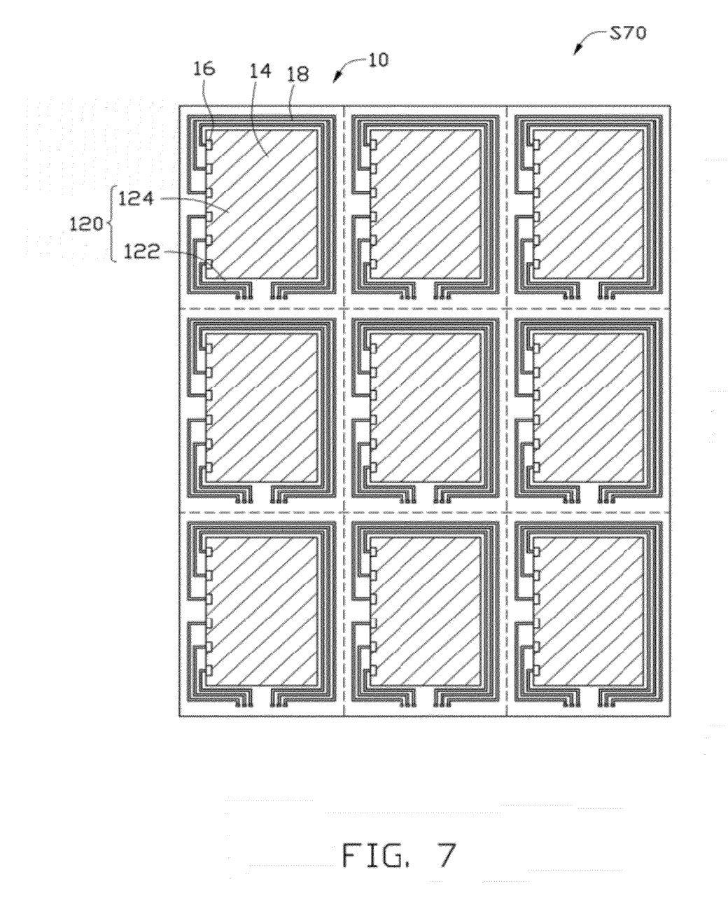

Referring to FIGS. 1-7, a method for making a plurality of touch panels 10 of one embodiment includes the steps of:

step (S10), providing a substrate 12 having a surface defining a plurality of target areas 120 with each including two areas: a touch-view area 124 and a trace area 122;

step (S20), forming an adhesive layer 13 on the surface of the substrate 12;

step (S30), solidifying a first part of the adhesive layer 13 on the trace areas 122;

step (S40), forming a carbon nanotube layer 19 on the adhesive layer 13;

step (S50), solidifying a second part of adhesive layer 13 on the touch-view areas 124 to fix the carbon nanotube layer 19 thereon;

step (S60), removing part of the carbon nanotube layer 19 on the trace areas 122 to obtain a plurality of transparent conductive layers 14 spaced from each other;

step (S70), forming electrodes 16 and conductive traces 18 on the first part of the adhesive layer 13 on each target area 120; and

step (S80), cutting and obtaining a plurality of touch panels 10.

In step (S10), the substrate 12 can be flat or curved and configured to support other elements. The substrate 12 is insulative and transparent. The substrate 12 can be made of rigid materials such as glass, quartz, diamond, plastic or any other suitable material. The substrate 12 can also be made of flexible materials such as polycarbonate (PC), polymethyl methacrylate acrylic (PMMA), polyimide (PI), polyethylene terephthalate (PET), polyethylene (PE), polyether polysulfones (PES), polyvinyl polychloride (PVC), benzocyclobutenes (BCB), polyesters, or acrylic resin. In one embodiment, the substrate 12 is a flat and flexible PET plate.

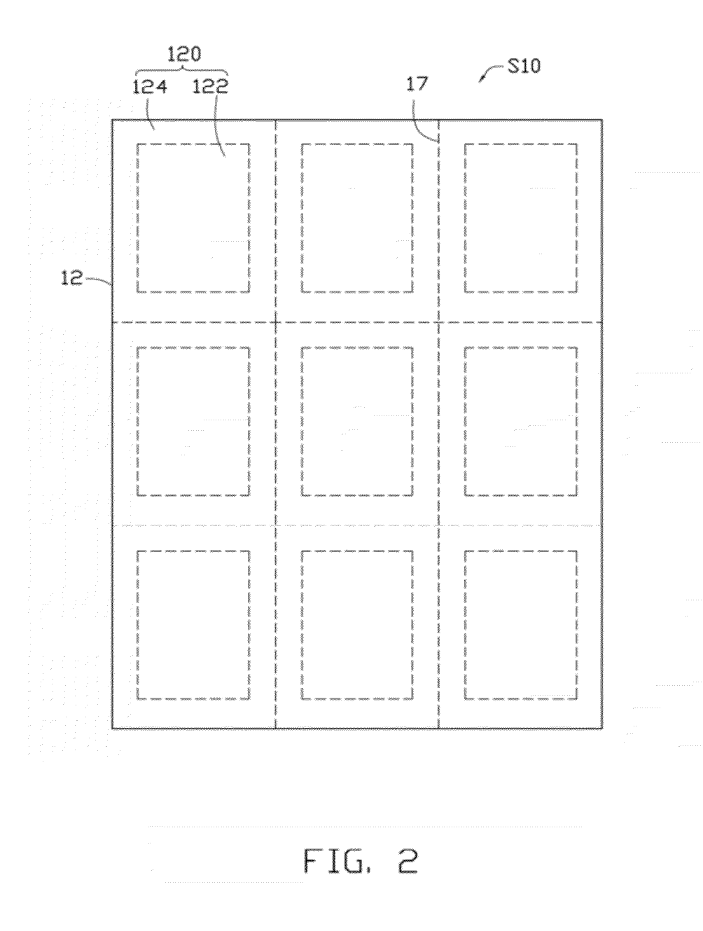

Referring to FIG. 2, the shape and size of the target areas 120 can be selected according to need. In one embodiment, the surface of the substrate 12 is divided into nine target areas 120 arranged in an array of three rows and three columns by four cutting lines 17. The target areas 120 have the same shape and size. The touch-view area 124 is typically a center area of the touch panel 10 which can be touched and viewed to realize the control function. The trace area 122 is usually a periphery area of the touch panel 10 which can be used to support the conductive trace 18. The touch-view area 124 has a relatively large area. The trace area 122 is located on at least one side of the touch-view area 124. The positional relationship of the touch-view area 124 and the trace area 122 can be selected according to need. In one embodiment, the shape of the touch panel 10 is a rectangle, the touch-view area 124 is the center region having a shape the same as that is the shape of touch panel 10 and surrounded by the trace area 122.

In step (S20), the adhesive layer 13 can be any adhesive which can be solidified on a certain condition. The adhesive layer 13 can be transparent, opaque, or translucent. In one embodiment, the transmittance of the adhesive layer 13 can be greater than 75%. The adhesive layer 13 can be made of materials such as hot plastic or UV (Ultraviolet Rays) glue, for example PVC or PMMA. The thickness of the adhesive layer 13 can be in a range from about 1 nanometer to about 500 micrometers. For example, the thickness is in a range from about 1 micrometer to about 2 micrometers. The adhesive layer 13 can be formed by spin-coating, spraying, or brushing. In one embodiment, the substrate 12 is a PET film. The adhesive layer 13 is an UV glue layer with a thickness of 1.5 micrometers and formed on the substrate 12 by spin-coating.

In step (S30), the method for solidifying the adhesive layer 13 depends on the material of the adhesive layer 13. The thermoplastic adhesive layer 13 can be solidified by partially cooling, the thermosetting adhesive layer 13 can be solidified by partially heating, and the UV glue adhesive layer 13 can be solidified by partially irradiating with ultraviolet light.

In one embodiment, the adhesive layer 13 is UV glue layer and can be solidified by steps of:

step (S301), sheltering the first part of the adhesive layer 13 on the touch-view area 124 of each target area 120 by a mask 15, wherein the mask 15 can be suspended above the adhesive layer 13;

step (S302), irradiating the second part of the adhesive layer 13 on the trace area 122 of each target area 120 with ultraviolet light, wherein the adhesive layer 13 is irradiated for about 2 seconds to about 30 seconds; and

step (S303), removing the mask 15.

In one embodiment, the adhesive layer 13 is irradiated for about 4 seconds. The first part of the adhesive layer 13 on the touch-view areas 124 will not be solidified because of the sheltering of the mask 15. The second part of the adhesive layer 13 on the trace areas 122 will be solidified after the ultraviolet light irradiating.

In step (S40), the carbon nanotube layer 19 can be formed by transfer printing a preformed carbon nanotube film, filtering and depositing a carbon nanotube suspension, or laying a free-standing carbon nanotube film. When the width of the free-standing carbon nanotube film is smaller than the width of the adhesive layer 13, a plurality of free-standing carbon nanotube films can be coplanarly placed on the adhesive layer 13 side by side. Each two contacting sides of each two adjacent free-standing carbon nanotube films can be overlapped with the cutting lines 17 between two adjacent target areas 120.

After the carbon nanotube layer 19 is placed on the adhesive layer 13, the carbon nanotube layer 19 on the trace areas 122 is only located on surface of the solidified adhesive layer 13 and connected with the solidified adhesive layer 13 by van der Waals attractive force. The carbon nanotube layer 19 on the touch-view areas 124 is infiltrated into the non-solidified adhesive layer 13 and will be fixed by the adhesive layer 13 in following step (S50). In one embodiment, part of the carbon nanotube layer 19 on the touch-view areas 124 is infiltrated into the non-solidified adhesive layer 13, and part of the carbon nanotube layer 19 on the touch-view areas 124 is exposed through of the adhesive layer 13. Furthermore, a step of pressing the carbon nanotube layer 19 can be performed after step (S40) to allow more carbon nanotubes of the carbon nanotube layer 19 to infiltrate into the non-solidified adhesive layer 13.

The carbon nanotube film includes a plurality of carbon nanotubes. The carbon nanotube film can be a substantially pure structure of the carbon nanotubes, with few impurities and chemical functional groups. A majority of the carbon nanotubes are arranged to extend along the direction substantially parallel to the surface of the carbon nanotube film. The carbon nanotubes in the carbon nanotube film can be single-walled, double-walled, or multi-walled carbon nanotubes. The length and diameter of the carbon nanotubes can be selected according to need, for example the diameter can be in a range from about 0.5 nanometers to about 50 nanometers and the length can be in a range from about 200 nanometers to about 900 nanometers. The thickness of the carbon nanotube film can be in a range from about 0.5 nanometers to about 100 micrometers, for example in a range from about 100 nanometers to about 200 nanometers. The carbon nanotube film has a good flexibility because of the good flexibility of the carbon nanotubes therein.

The carbon nanotubes of the carbon nanotube film can be arranged orderly to form an ordered carbon nanotube structure or disorderly to form a disordered carbon nanotube structure. The term ‘disordered carbon nanotube structure’ includes, but is not limited to, to a structure where the carbon nanotubes are arranged along many different directions, and the aligning directions of the carbon nanotubes are random. The number of the carbon nanotubes arranged along each different direction can be almost the same (e.g. uniformly disordered). The carbon nanotubes in the disordered carbon nanotube structure can be entangled with each other. The term ‘ordered carbon nanotube structure’ includes, but is not limited to, a structure where the carbon nanotubes are arranged in a consistently systematic manner, e.g., the carbon nanotubes are arranged approximately along a same direction and/or have two or more sections within each of which the carbon nanotubes are arranged approximately along a same direction (different sections can have different directions).

In one embodiment, the carbon nanotube film is a free-standing structure. The term “free-standing structure” means that the carbon nanotube film can sustain the weight of itself when it is hoisted by a portion thereof without any significant damage to its structural integrity. Thus, the carbon nanotube film can be suspended by two spaced supports. The free-standing carbon nanotube film can be drawn from a carbon nanotube array and then placed on the adhesive layer 13 directly and easily.

In one embodiment, the carbon nanotube film can be made by the steps of: growing a carbon nanotube array on a wafer by chemical vapor deposition method; and drawing the carbon nanotubes of the carbon nanotube array to from the carbon nanotube film. During the drawing step, the carbon nanotubes are joined end-to-end by van der Waals attractive force therebetween along the drawing direction. The carbon nanotube film has the smallest resistance along the drawing direction and the greatest resistance along a direction perpendicular to the drawing direction. Thus, the carbon nanotube film is resistance anisotropy. Furthermore, the carbon nanotube film can be etched or irradiated by laser. After being irradiated by laser, a plurality of parallel carbon nanotube conductive strings will be formed and the resistance anisotropy of the carbon nanotube film will not be damaged because the carbon nanotube substantially extending not along the drawing direction are removed by burning. Each carbon nanotube conductive string comprises a plurality of carbon nanotubes joined end-to-end by van der Waals attractive force.

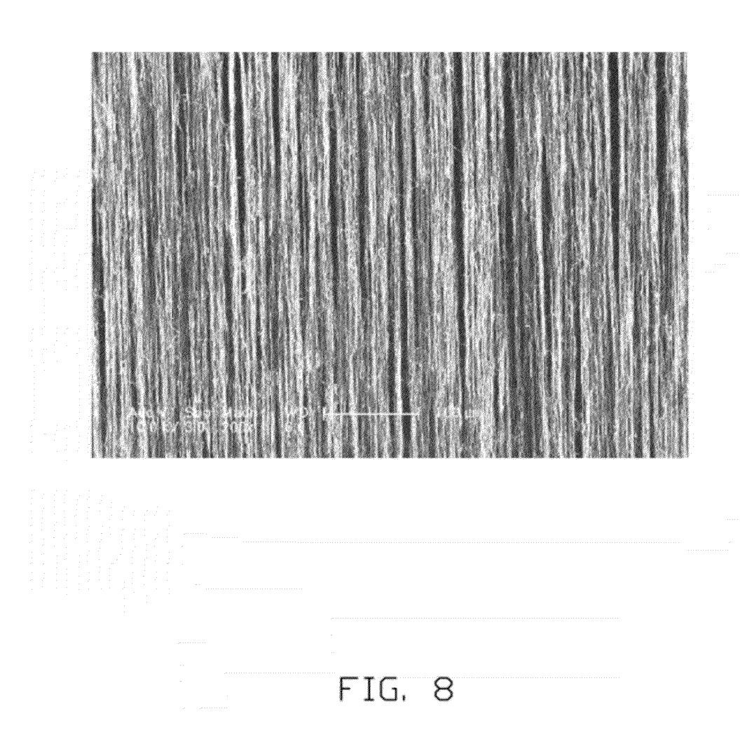

In one embodiment, the carbon nanotube layer 19 is a single carbon nanotube film. The carbon nanotube film includes a plurality of successive and oriented carbon nanotubes joined end-to-end by van der Waals attractive force therebetween. The carbon nanotube film is a free-standing film. Referring to FIG. 8, each carbon nanotube film includes a plurality of successively oriented carbon nanotube segments joined end-to-end by van der Waals attractive force therebetween. Each carbon nanotube segment includes a plurality of carbon nanotubes parallel to each other, and combined by van der Waals attractive force therebetween. Some variations can occur in the carbon nanotube film. The carbon nanotubes in the carbon nanotube film are oriented along a preferred orientation. The carbon nanotube film can be treated with an organic solvent to increase the mechanical strength and toughness and reduce the coefficient of friction of the carbon nanotube film. A thickness of the carbon nanotube film can range from about 0.5 nanometers to about 100 micrometers.

The carbon nanotube layer 19 can include at least two stacked carbon nanotube films. In other embodiments, the carbon nanotube layer 19 can include two or more coplanar carbon nanotube films. Additionally, when the carbon nanotubes in the carbon nanotube film are aligned along one preferred orientation, an angle can exist between the orientations of carbon nanotubes in adjacent films, whether stacked or adjacent. Adjacent carbon nanotube films can be combined by only the van der Waals attractive force therebetween. An angle between the aligned directions of the carbon nanotubes in two adjacent carbon nanotube films can range from about 0 degrees to about 90 degrees. When the angle between the aligned directions of the carbon nanotubes in adjacent stacked carbon nanotube films is larger than 0 degrees, a plurality of micropores is defined by the carbon nanotube film. Stacking the carbon nanotube films will also add to the structural integrity of the carbon nanotube film.

In step (S50), the method for solidifying the adhesive layer 13 is same as the method for solidifying the adhesive layer 13 provided in step (S30). The non-solidified adhesive layer 13 is solidified in step (S50). Because part of the carbon nanotube layer 19 is infiltrated into the non-solidified adhesive layer 13, the carbon nanotube layer 19 on the touch-view areas 124 is fixed by the adhesive layer 13 in step (S50). The carbon nanotube layer 19 on the trace areas 122 will not be fixed by the adhesive layer 13. In one embodiment, the adhesive layer 13 on the touch-view areas 124 is solidified by irradiating with ultraviolet light.

In step (S60), the carbon nanotube layer 19 on the trace areas 122 can be removed by a method such as stripping by an adhesive tape or peeling by a roller having an adhesive outer surface. Because the bonding force between the carbon nanotube layer 19 and the adhesive layer 13 on the trace areas 122 is weak, the carbon nanotube layer 19 on the trace areas 122 will be removed easily by the adhesive tape or the roller having an adhesive outer surface. In one embodiment, the carbon nanotube layer 19 on the trace areas 122 is stripped by an adhesive tape. Compared to the process of forming pattern ITO layer by ion-beam sputtering and laser beam etching, the process of making the transparent conductive layer 14 is simple and low cost. Furthermore, the carbon nanotube layer 19 can be removed by a method such as laser-beam etching, ion-beam etching, or electron-beam etching.

In step (S70), the electrode 16 and the conductive trace 18 can be made of material such as metal, carbon nanotube, conductive silver paste, or ITO and made by etching a metal film, etching an ITO film, or printing a conductive silver paste. In one embodiment, both the conductive trace 18 and the electrodes 16 are made of conductive silver paste and made by printing conductive silver paste concurrently. The conductive silver paste can include about 50% to about 90% (by weight) of the metal powder, about 2% to about 10% (by weight) of the glass powder, and about 8% to about 40% (by weight) of the binder.

The electrode 16 can be located on only the touch-view areas 124, only the trace areas 122, or both the touch-view areas 124 and the trace areas 122. The position of the electrode 16 depends on the work principle of the touch panel 10 and the detection methods of the touch-point. The number of the electrode 16 depends on the area and resolution of the touch panel 10. In one embodiment, the touch panel 10 includes six electrodes 16 spaced from each other and arranged on one side of the transparent conductive layer 14. The conductive trace 18 includes a plurality of conductive wires and located only the trace areas 122.

The order of the step (S60) and step (S70) can be interchangeable. Thus, the conductive trace 18 is formed on and covers the carbon nanotube layer 19. In this way, the carbon nanotube layer 19 is removed by a method such as laser-beam etching, ion-beam etching, or electron-beam etching. The conductive trace 18 can be used as a mask for etching. Thus, part of the carbon nanotube layer 19 will be maintained between the conductive trace 18 and the adhesive layer 13 or between the electrode 16 and the adhesive layer 13.

In step (S80), the step of cutting can be performed by a laser beam or a mechanical device such as a blade. In one embodiment, the target areas 120 of the substrate 12 are cut and separated from each other by blade from the cutting lines 17. The blade can move along the row direction firstly and then along the column direction. Thus, the plurality of touch panels 10 is obtained.

Furthermore, an optically clear adhesive (OCA) layer and a cover lens can be applied on the substrate 12 to cover all the transparent conductive layers 14, the electrodes 16, and the conductive traces 18 before step (S80).

It is to be understood that the above-described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope of the disclosure but do not restrict the scope of the disclosure.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. A method for making a plurality of touch panels, the method comprising:
providing a substrate having a surface, the surface defining a plurality of target areas, each target area comprising a touch-view area and a trace area;
applying an adhesive layer on the surface of the substrate, wherein the adhesive layer comprises a first part on the trace area of each target area and a second part on the touch-view area of each target area;
solidifying the first part of the adhesive layer;
applying a carbon nanotube layer on the adhesive layer;
solidifying the second part of the adhesive layer;
removing the carbon nanotube layer that on the trace area of each target area to obtain a plurality of transparent conductive layers spaced from each other and each in one of the target areas; and
forming an electrode and a conductive trace on the trace area of each target area, wherein in each target area, the conductive trace is electrically connected with one transparent conductive layer via the electrode.

2. The method of claim 1, wherein the adhesive layer is formed by spin-coating, spraying, or brushing.

3. The method of claim 1, wherein the adhesive layer comprises thermoplastic and is solidified by cooling.

4. The method of claim 1, wherein the adhesive layer comprises thermosetting material and is solidified by heating.

5. The method of claim 1, wherein the adhesive layer comprises UV glue and is solidified by ultraviolet light irradiation.

6. The method of claim 5, wherein the solidifying the first part of the adhesive layer comprises:
sheltering the first part of the adhesive layer by a mask;
irradiating the first part of the adhesive layer with an ultraviolet light; and
removing the mask.

7. The method of claim 6, wherein the mask is suspended above the adhesive layer.

8. The method of claim 1, wherein the carbon nanotube layer is formed by filtering and depositing a carbon nanotube suspension.

9. The method of claim 1, wherein the carbon nanotube layer is formed by steps of:
drawing a free-standing carbon nanotube film from a carbon nanotube array; and
laying the free-standing carbon nanotube film on the adhesive layer directly.

10. The method of claim 9, wherein a plurality of carbon nanotube films are coplanarly laid on the adhesive layer side by side, and each two contacting sides of each two adjacent carbon nanotube films overlap a cutting line between two adjacent target areas.

11. The method of claim 1, wherein after applying the carbon nanotube layer on the adhesive layer, the carbon nanotube layer on the trace area of each target area is only located on a surface of the first part of the adhesive layer, and the carbon nanotube layer on the touch-view area of each target area is infiltrated into the second part of the adhesive layer.

12. The method of claim 11, wherein the carbon nanotube layer on the touch-view area of each target area comprises carbon nanotubes infiltrated into and extending out of the second part of the adhesive layer.

13. The method of claim 1, further comprising pressing the carbon nanotube layer after applying the carbon nanotube layer on the adhesive layer.

14. The method of claim 1, wherein the carbon nanotube layer on the trace area of each target area is removed by stripping, wherein the stripping is done by an adhesive tape or peeling by a roller having an adhesive outer surface.

15. The method of claim 1, wherein the carbon nanotube layer on the trace area of each target area is removed by laser-beam etching, ion-beam etching, or electron-beam etching.

16. The method of claim 1, wherein the electrode and the conductive trace are made of material selected from the group consisting of metal, carbon nanotube, conductive silver paste, and ITO and made by etching a metal film, etching an ITO film, or printing a conductive silver paste.

17. The method of claim 1, further comprising a step of cutting the substrate after forming the electrode and the conductive trace on the trace area of each target area.

18. The method of claim 17, wherein the step of cutting is performed by a laser beam or a mechanical device.

19. A method for making a plurality of touch panels, the method comprising:
providing a substrate having a surface, the surface defining a plurality of target areas, each target area comprising a touch-view area and a trace area;
applying an adhesive layer on the surface of the substrate, wherein the adhesive layer comprises a first part on the trace area of each target area and a second part on the touch-view area of each target area;
solidifying the first part of the adhesive layer;
applying a carbon nanotube layer on the adhesive layer;
solidifying the second part of the adhesive layer;
forming an electrode and a conductive trace on the trace area of each target area; and
removing the carbon nanotube layer on the trace area of each target area after forming the electrode and the conductive trace on the trace area of each target area.

20. The method of claim 19, further comprising a step of cutting the substrate after removing the carbon nanotube layer on the trace area of each target area.
